(19) United States
(12) Patent Application Publication
(10) Pub. No.: US 2026/0200956 A1
(43) Pub. Date: Jul. 16, 2026

(54) NOVEL ALKOXYAMINOSILYLAMINE COMPOUND, METHOD FOR PREPARING THE SAME, COMPOSITION FOR DEPOSITING SILICON-CONTAINING THIN FILM INCLUDING THE SAME, AND METHOD FOR MANUFACTURING SILICON-CONTAINING THIN FILM USING THE SAME

(71) Applicant: DNF CO., LTD., Daejeon (KR)

(72) Inventors: Sung Gi KIM, Daejeon (KR); Yu Jin CHO, Daejeon (KR); Seung SON, Daejeon (KR); Jiho RYU, Daejeon (KR); Jun Hee CHO, Daejeon (KR); Haeng-Don LIM, Daejeon (KR); Gun Joo PARK, Daejeon (KR)

(21) Appl. No.: 19/565,191

(22) Filed: Mar. 12, 2026

Related U.S. Application Data
(63) Continuation of application No. PCT/KR2024/012924, filed on Aug. 29, 2024.

(30) Foreign Application Priority Data
Sep. 12, 2023 (KR) 10-2023-0120792

(51) Int. Cl. C07F 7/08; C23C 16/24; C23C 16/455

(52) U.S. Cl. CPC C07F 7/081; C23C 16/24; C23C 16/45553

(57) ABSTRACT

Provided are a novel alkoxyaminosilylamine compound, a method for preparing the same, a composition for depositing a silicon-containing thin film including the same, and a method for manufacturing a silicon-containing thin film using the same, and since the alkoxyaminosilylamine compound according to the present disclosure is thermally stable and highly volatile and reactive, it is very useful for stably manufacturing a silicon-containing thin film having excellent characteristics in a large temperature range.

### CROSS REFERENCE TO RELATED APPLICATIONS

The present application is a continuation of International Application No. PCT/KR2024/012924 entitled “NOVEL ALKOXYAMINOSILYLAMINE COMPOUND, PREPARATION METHOD THEREFOR, SILICON-CONTAINING THIN FILM DEPOSITION COMPOSITION COMPRISING SAME, AND METHOD FOR MANUFACTURING SILICON-CONTAINING THIN FILM BY USING SAME”, and filed on Aug. 29, 2024. International Application No. PCT/KR2024/012924 claims priority to Republic of Korea Patent Application No. 10-2023-0120792 filed on Sep. 12, 2023. The entire contents of each of the above-listed applications are hereby incorporated by reference for all purposes.

### TECHNICAL FIELD

The disclosure relates to a novel alkoxyaminosilylamine compound, a method for preparing the same, a composition for depositing a silicon-containing thin film including the same, and a method for manufacturing a silicon-containing thin film using the same.

### BACKGROUND ART

A silicon-containing thin film is manufactured into various forms of thin films such as a silicon film, a silicon oxide film, a silicon nitride film, a silicon carbonitride film, and a silicon oxynitride film by various deposition processes in the semiconductor field, and recently, a polycrystalline silicon thin film has been used in a thin film transistor (TFT), a solar battery, and the like and its application fields are becoming increasingly diverse.

A representative technology known for the manufacture of a silicon-containing thin film includes chemical vapor deposition (MOCVD) in which a silicon precursor in the form of mixed gas reacts with a reaction gas to form a film on a substrate surface, or directly reacts on the surface to form a film and atomic layer deposition (ALD) in which a silicon precursor in a gas form is physically or chemically adsorbed on a substrate surface, and then forms a film by subsequently adding reaction gas, and various thin film manufacturing technologies using the technologies such as low pressure chemical vapor deposition (LPCVD), and plasma-enhanced chemical vapor deposition (PECVD) and plasma-enhanced atomic layer deposition (PEALD) which allow deposition at a low temperature using plasma, are applied to next generation semiconductor and display device manufacturing processes and used in ultrathin film deposition having uniform and excellent properties in ultrafine pattern formation and a nano-thickness.

A precursor used for forming a silicon-containing thin film is representatively compounds in the form of silane, silane chloride, aminosilane, and alkoxysilane, and as a specific example, compounds in the form of silane chloride such as dichlorosilane (SiH₂Cl₂) and hexachlorodisilane (Cl₃SiSiCl₃), trisilylamine (N(SiH₃)₃), bis-diethylaminosilane (H₂Si(N(CH₂CH₃)₂)₂), di-isopropylaminosilane (H₃SiN(i-C₃H₇)₂), and the like are included, which are being used in semiconductor manufacture and display manufacture mass production processes.

However, due to miniaturization and an increased aspect ratio of elements resulting from ultrahigh integration of the elements, and diversification of element materials, a technology for forming an ultrafine thin film having a uniform small thickness and excellent electrical properties at a desired low temperature is required, and thus, a high temperature process at 600° C. or higher using a conventional silicon precursor, step coverage, etching properties, and the physical and electrical properties of the thin film are becoming a problem, and thus, development of a novel and improved silicon precursor is demanded.

### DISCLOSURE

### Technical Problem

An object of the present disclosure is to provide a novel alkoxyaminosilylamine compound and a method for preparing the same

Specifically, an embodiment of the present disclosure is directed to providing an alkoxyaminosilylamine compound which is useful as a precursor for forming a silicon-containing thin film and is thermally stable and highly volatile.

Specifically, an embodiment of the present disclosure is directed to providing a novel alkoxyaminosilylamine compound which is a precursor compound capable of forming a stable silicon-containing thin film with excellent reactivity in a broad temperature range.

Another object of the present disclosure is to provide a composition for depositing a silicon-containing thin film including the alkoxyaminosilylamine compound according to an exemplary embodiment of the present disclosure.

Still another object of the present disclosure is to provide a method for forming a silicon-containing thin film having excellent characteristics, using the alkoxyaminosilylamine compound or a composition for depositing a silicon-containing thin film including the same.

### Technical Solution

In one general aspect, an alkoxyaminosilylamine compound represented by the following Chemical Formula 1 is provided:

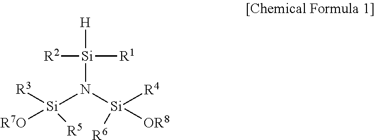

wherein
R¹ to R⁴ are independently of one another hydrogen, C1-C10 alkyl, C2-C10 alkenyl, or halogen; and
R⁵ to R⁸ are independently of one another C1-C10 alkyl.

In Chemical Formula 1 of the compound according to an exemplary embodiment, R¹ to R⁴ may be independently of one another hydrogen, C1-C5 alkyl, C2-C5 alkenyl, or halogen; and R⁵ to R⁸ may be independently of one another C1-C5 alkyl.

In Chemical Formula 1 of the compound according to an exemplary embodiment, R¹ to R⁴ may be independently of one another hydrogen or C1-C5 alkyl; and R⁵ to R⁸ may be independently of one another C1-C5 alkyl.

In Chemical Formula 1 of the compound according to an exemplary embodiment, R¹ to R⁴ may be independently of one another hydrogen, C1-C3 alkyl, C2-C4 alkenyl, or halogen; and R⁵ to R⁸ may be independently of one another C1-C3 alkyl.

In Chemical Formula 1 of the compound according to an exemplary embodiment, R¹ to R⁴ may be independently of one another hydrogen or C1-C3 alkyl; and R⁵ to R⁸ may be independently of one another C1-C3 alkyl.

The compound of Chemical Formula 1 according to an exemplary embodiment may be at least one selected from the following structures:

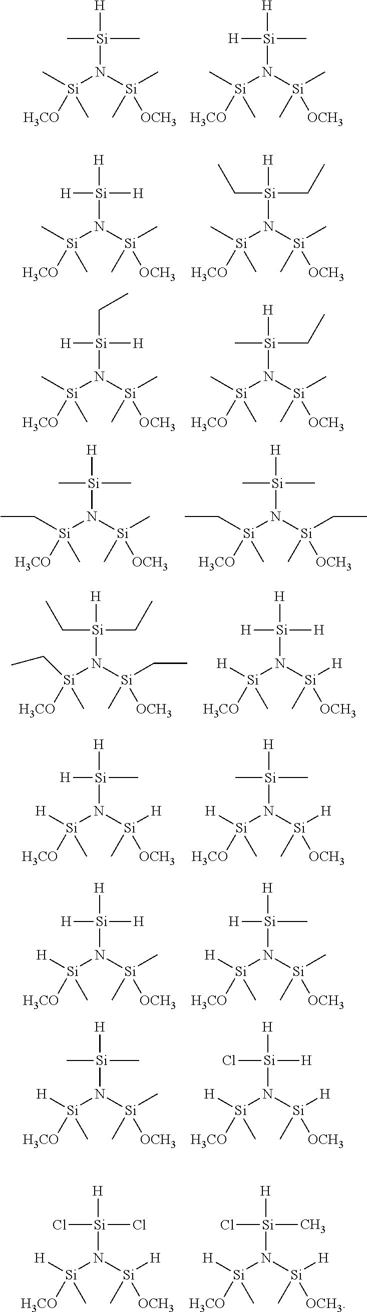

In another general aspect, a method for preparing an alkoxyaminosilylamine compound includes: reacting a compound of the following Chemical Formula 3 and a compound of the following Chemical Formula 4 in the presence of C1-C5 alkyllithium to prepare an alkoxyaminosilylamine compound of the following Chemical Formula 1:

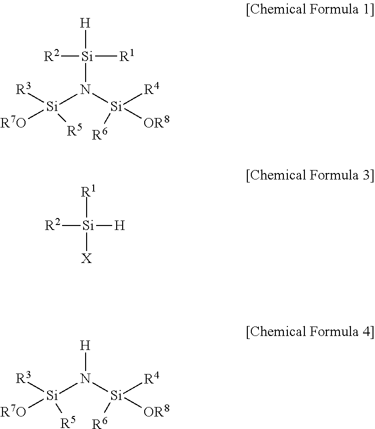

wherein
R¹ to R⁴ are independently of one another hydrogen, C1-C10 alkyl, C2-C10 alkenyl, or halogen;
R⁵ to R⁸ are independently of one another C1-C10 alkyl; and
X is a halogen.

The method for preparing an alkoxyaminosilylamine compound according to an exemplary embodiment may include: reacting a compound of the following Chemical Formula 4 and a compound of the following Chemical Formula 5 in the presence of C1-C5 alkyllithium to prepare a compound of the following Chemical Formula 6; and adding a reducing agent to the compound of Chemical Formula 6 to prepare an alkoxyaminosilylamine compound of the following Chemical Formula 1-1:

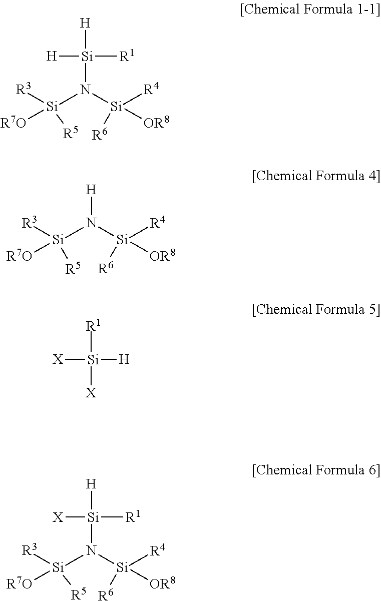

wherein
R¹, R³, and R⁴ are independently of one another hydrogen, C1-C10 alkyl, C2-C10 alkenyl, or halogen;
R⁵ to R⁸ are independently of one another C1-C10 alkyl; and
X is a halogen.

In another general aspect, a composition for depositing a silicon-containing thin film includes an alkoxyaminosilylamine compound represented by the following Chemical Formula 2:

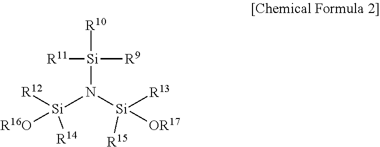

wherein
R⁹ to R¹³ are independently of one another hydrogen, C1-C10 alkyl, C2-C10 alkenyl, or halogen; and
R¹⁴ to R¹⁷ are independently of one another C1-C10 alkyl.

In Chemical Formula 2 of the composition for depositing a silicon-containing thin film according to an exemplary embodiment, R⁹ to R¹³ may be independently of one another hydrogen, C1-C5 alkyl, C2-C5 alkenyl, or halogen; and R¹⁴ to R¹⁷ may be independently of one another C1-C5 alkyl.

The compound of Chemical Formula 2 according to an exemplary embodiment may be at least one selected from the following structures:

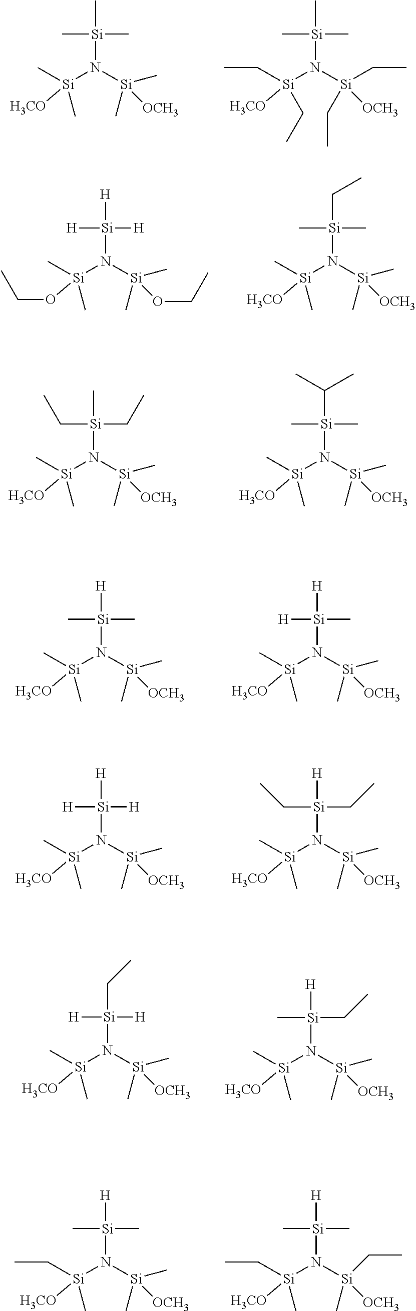

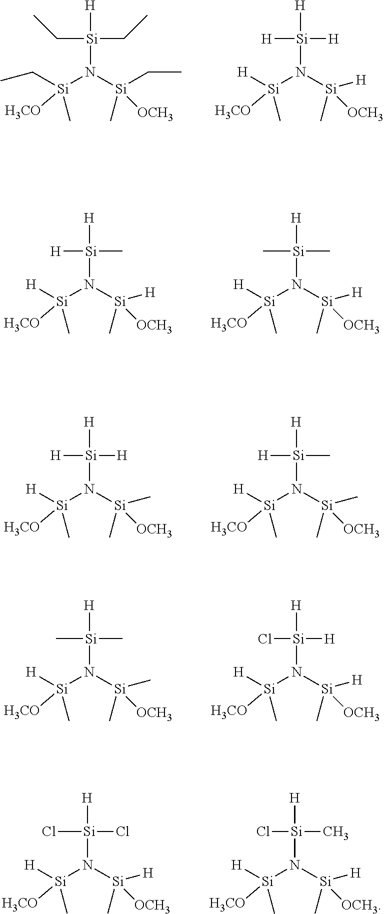

In another general aspect, a method for manufacturing a silicon-containing thin film includes manufacturing a thin film using the alkoxyaminosilylamine compound according to an exemplary embodiment.

In still another general aspect, a method for manufacturing a silicon-containing thin film includes manufacturing a thin film using the composition for depositing a silicon-containing thin film according to an exemplary embodiment.

### Advantageous Effects

The alkoxyaminosilylamine compound according to the present disclosure may be provided as a precursor of a silicon-containing thin film which is thermally stable and highly volatile and form a silicon-containing thin film having excellent characteristics.

In addition, the alkoxyaminosilylamine compound according to the present disclosure may have excellent reactivity in a broad temperature range when a silicon-containing thin film is manufactured using the compound.

In addition, the composition for depositing a silicon-containing thin film according to an exemplary embodiment of the present disclosure allows manufacture of a high-quality silicon-containing thin film by including the alkoxyaminosilylamine compound according to an exemplary embodiment of the present disclosure.

In addition, the method for preparing an alkoxyaminosilylamine compound according to an exemplary embodiment allows manufacture of a high-purity alkoxyaminosilylamine compound with a high yield.

### DESCRIPTION OF DRAWINGS

FIG. 1 is a thermogravimetric analysis (TGA) graph of the alkoxyaminosilylamine compounds prepared in Examples 1 and 2.

FIG. 2 is a differential scanning calorimetry (DSC) graph of the alkoxyaminosilylamine compounds prepared in Examples 1 and 2.

### BEST MODE

Hereinafter, the present disclosure will be described in detail. Technical terms and scientific terms used in the present specification have the general meaning understood by those skilled in the art to which the present disclosure pertains unless otherwise defined, and a description for the known function and configuration obscuring the present disclosure will be omitted in the following description.

The term “C_{A}-C_{B}” in the present specification refers to “having A or more and B or fewer carbon atoms”, and the term “A to B” refers to “A or more and B or less”.

The term “alkyl” of the present specification is a monovalent substituent and includes both linear or branched forms.

The alkyl may have 1 to 10, specifically 1 to 5, and more specifically 1 to 3 carbon atoms.

The alkyl includes, as an example, methyl, ethyl, n-propyl, i-propyl, n-butyl, i-butyl, t-butyl, pentyl, hexyl, and the like, but is not limited thereto.

The term “alkoxy” of the present specification is a —O-alkyl radical in which “alkyl” is as defined above. A specific example thereof includes methoxy, ethoxy, isopropoxy, butoxy, isobutoxy, t-butoxy, and the like, but is not limited thereto.

The term “alkenyl” in the present specification refers to a linear or branched hydrocarbon having at least one carbon-carbon double bond.

The alkenyl may have 2 to 10, specifically 2 to 7, and more specifically 2 to 5 carbon atoms.

The alkenyl includes, as an example, vinyl, allyl, butenyl, isobutenyl, pentenyl, hexenyl, and the like, but is not limited thereto.

The term “halogen” of the present specification refers to a Group 17 element, and may be any one selected from F, Cl, Br, and I.

In addition, the term “comprise” in the present specification is an open-ended description having a meaning equivalent to the term such as “is/are provided”, “contain”, “have”, or “is/are characterized”, and does not exclude elements, materials, or processes which are not further listed.

In addition, the singular form used in the present specification may be intended to also include a plural form, unless otherwise indicated in the context.

The term “thermal stability” of the present specification may refer to physical properties which are not changed even during a continuous heating process or a high-temperature process, and specifically, refers to not causing a structural change even when exposed to the harsh conditions described above for a long time.

The term “silicon-containing thin film having excellent characteristics” of the present specification refers to a high-quality silicon-containing thin film having a high silicon content, excellent thermal stability, and excellent durability.

In the present specification, “normal temperature” may refer to a temperature in a state without artificial temperature adjustment, and, for example, the normal temperature may be 20° C. to 40° C., 20° C. to 30° C., or 23° C. to 26° C.

The present disclosure provides a novel alkoxyaminosilylamine compound which is useful as a precursor for manufacturing a silicon-containing thin film, and the alkoxyaminosilylamine compound of the present disclosure is represented by the following Chemical Formula 1:

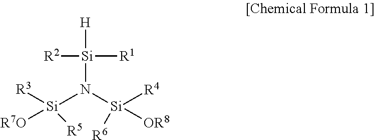

wherein
R¹ to R⁴ are independently of one another hydrogen, C1-C10 alkyl, C2-C10 alkenyl, or halogen; and
R⁵ to R⁸ are independently of one another C1-C10 alkyl.

The alkoxyaminosilylamine compound of the present disclosure has a structure in which an alkoxy functional group is introduced to a silicon atom having a trisilylamine structure, and since it has improved reactivity with lower activation energy due to the alkoxy functional group introduced to the silicon atom and does not produce nonvolatile by-products, it may easily form a high-purity silicon-containing thin film with a high deposition rate.

In the alkoxyaminosilylamine compound according to an exemplary embodiment, in Chemical Formula 1, R¹ to R⁴ may be independently of one another hydrogen, C1-C5 alkyl, C2-C5 alkenyl, or halogen; and R⁵ to R⁸ may be independently of one another C1-C5 alkyl.

In the alkoxyaminosilylamine compound according to an exemplary embodiment, in Chemical Formula 1, R¹ to R⁴ may be independently of one another hydrogen or C1-C5 alkyl; and R⁵ to R⁸ may be independently of one another C1-C5 alkyl.

In the alkoxyaminosilylamine compound according to an exemplary embodiment, in Chemical Formula 1, R¹ to R⁴ may be independently of one another hydrogen, C1-C3 alkyl, C2-C4 alkenyl, or halogen; and R⁵ to R⁸ may be independently of one another C1-C3 alkyl.

In the alkoxyaminosilylamine compound according to an exemplary embodiment, in Chemical Formula 1, R¹ to R⁴ may be independently of one another hydrogen or C1-C3 alkyl; and R⁵ to R⁸ may be independently of one another C1-C3 alkyl.

Chemical Formula 1 according to a specific example may be selected from the following compounds, but is not limited thereto.

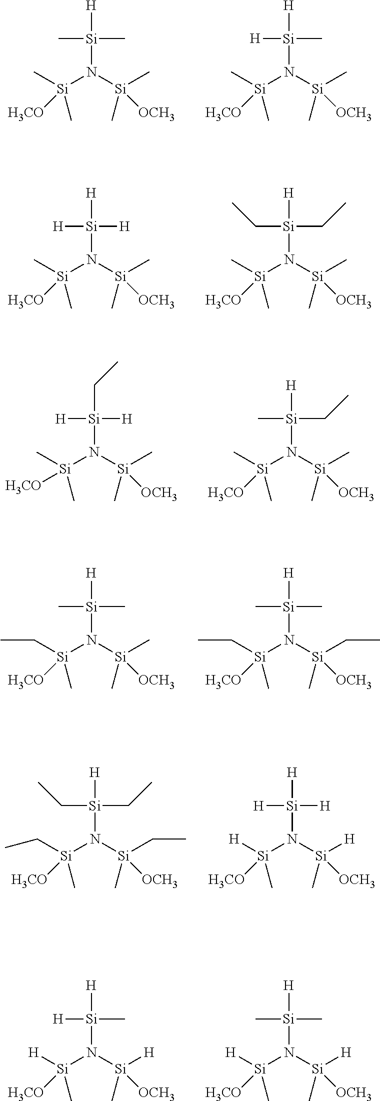

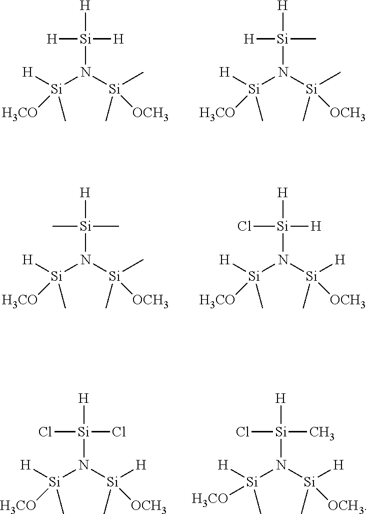

In addition, the present disclosure provides a method for preparing the alkoxyaminosilylamine compound.

As an exemplary embodiment, a method for preparing an alkoxyaminosilylamine compound including: reacting a compound of the following Chemical Formula 3 and a compound of the following Chemical Formula 4 in the presence of C1-C5 alkyllithium to prepare an alkoxyaminosilylamine compound of the following Chemical Formula 1 is provided:

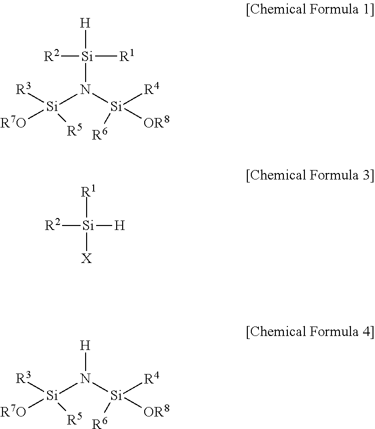

wherein
R¹ to R⁴ are independently of one another hydrogen, C1-C10 alkyl, C2-C10 alkenyl, or halogen;
R⁵ to R⁸ are independently of one another C1-C10 alkyl; and
X is a halogen.

In the preparation method, the alkyllithium may be a compound in which lithium is bonded to C1-C5 alkyl, specifically, methyllithium, ethyllithium, or n-butyllithium, preferably n-butyllithium.

In the preparation method, the halogen may be any one halogen selected from F, Cl, Br, and I, and preferably X may be C1.

The method for preparing an alkoxyaminosilylamine compound according to an exemplary embodiment may include: reacting a compound of the following Chemical Formula 4 and a compound of the following Chemical Formula 5 in the presence of C1-C5 alkyllithium to prepare a compound of the following Chemical Formula 6; and adding a reducing agent to the compound of Chemical Formula 6 to prepare an alkoxyaminosilylamine compound of the following Chemical Formula 1-1:

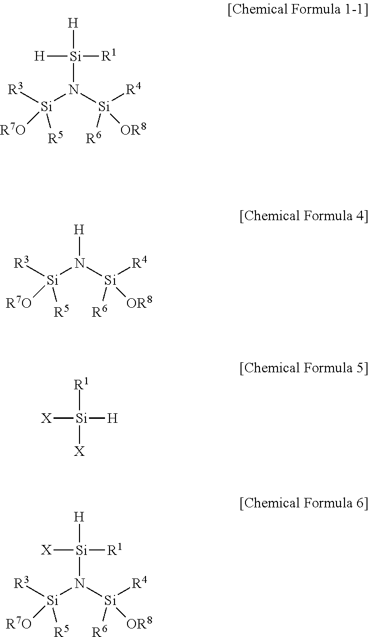

wherein
R¹, R³, and R⁴ are independently of one another hydrogen, C1-C10 alkyl, C2-C10 alkenyl, or halogen;
R⁵ to R⁸ are independently of one another C1-C10 alkyl; and
X is a halogen.

In the preparation method, the alkyllithium may be a compound in which lithium is bonded to C1-C5 alkyl, specifically, methyllithium, ethyllithium, or n-butyllithium, preferably n-butyllithium.

In the preparation method, the halogen may be any one halogen selected from F, Cl, Br, and I, and preferably X may be C1.

In the preparation method, as the reducing agent, a compound which may introduce hydrogen to a product by a reaction may be preferably used. Specifically, the reducing agent may be a metal hydride which may provide hydrogen, and as an example, may be one or more selected from CaH₂, LiAlH₄, LiBH₄, NaBH₄, NaH, LiH, and KH. More preferably, the reducing agent may be LiAlH₄ or LiH, but is not limited thereto. The reducing agent may replace the halogen atom of Chemical Formula 6 with hydrogen by adding it to Chemical Formula 6, which is thus preferred.

According to an exemplary embodiment, all of the reactions may be performed in an organic solvent, specifically one or a mixed organic solvent of two or more selected from hexane, diethyl ether, toluene, tetrahydrofuran, and the like, but are not limited thereto.

In addition, a reaction temperature in all of the reactions may be used at a temperature used in common organic synthesis, but may vary depending on a reaction time, a reaction material, and amounts of starting materials.

After the reaction, purity may be increased by removing by-products through filtration, extraction, recrystallization, distillation, sublimation, chromatography, and the like.

Since the alkoxyaminosilylamine compound prepared by the method is thermally stable and highly volatile, it may be used in forming a silicon-containing thin film having good characteristics, and also has excellent reactivity in a broad temperature range, so that the silicon-containing thin film may be stably manufactured.

In addition, according to the method for preparing the alkoxyaminosilylamine compound, a high-purity alkoxyaminosilylamine compound may be prepared with a high yield.

In addition, the present disclosure provides a composition for depositing a silicon-containing thin film including a compound represented by the following Chemical Formula 2:

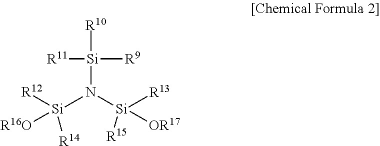

wherein R⁹ to R¹³ are independently of one another hydrogen, C1-C10 alkyl, C2-C10 alkenyl, or halogen; and R¹⁴ to R¹⁷ are independently of one another C1-C10 alkyl.

In Chemical Formula 2 of the composition for depositing a silicon-containing thin film according to an exemplary embodiment, R⁹ to R¹³ may be independently of one another hydrogen, C1-C5 alkyl, C2-C5 alkenyl, or halogen; and R¹⁴ to R¹⁷ may be independently of one another C1-C5 alkyl.

In Chemical Formula 2 of the composition for depositing a silicon-containing thin film according to an exemplary embodiment, R⁹ to R¹³ may be independently of one another hydrogen, C1-C3 alkyl, C2-C3 alkenyl, or halogen; and R¹⁴ to R¹⁷ may be independently of one another C1-C3 alkyl.

The alkoxyaminosilylamine compound of the present disclosure included in the composition for depositing a silicon-containing thin film has a structure in which an alkoxy functional group is introduced to a silicon atom having a trisilylamine structure, and since it has improved reactivity with lower activation energy due to the alkoxy functional group introduced to the silicon atom and does not produce nonvolatile by-products, it may easily form a high-purity silicon-containing thin film with a high deposition rate.

In addition, since the content of a silicon atom in the molecule is high, the composition for depositing a silicon-containing thin film including the compound allows easy deposition of a high-quality silicon-containing thin film with a high deposition rate and has high thermal stability, so that a thin film having high durability and excellent purity may be manufactured.

The composition for depositing a silicon-containing thin film of the present disclosure may be included within the content range which may be recognized by a person skilled in the art considering film formation conditions or thin film thickness, properties, and the like of the thin film.

Chemical Formula 2 according to a specific example may be selected from the following structures, but is not limited thereto:

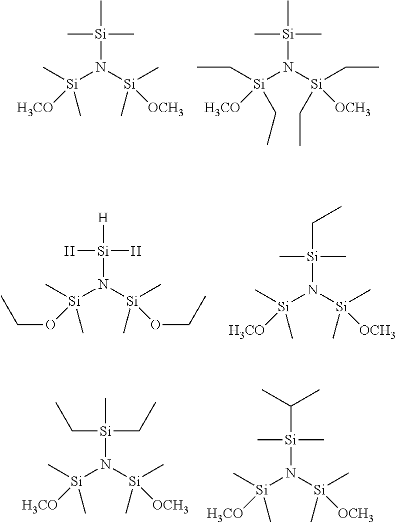

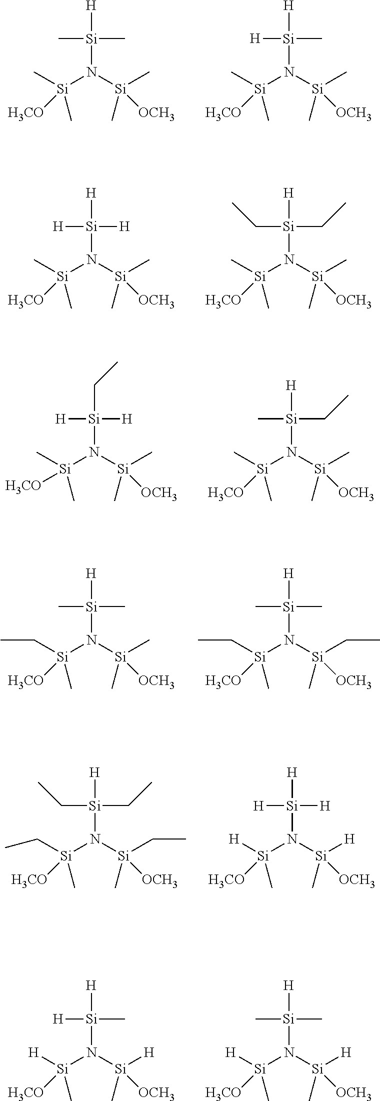

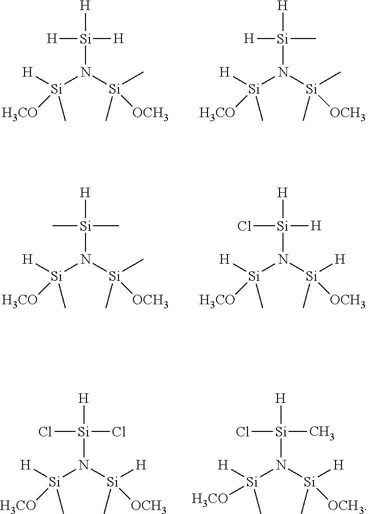

In addition, the present disclosure provides a method for manufacturing a silicon-containing thin film including manufacturing a thin film using the alkoxyaminosilylamine compound or the composition for depositing a silicon-containing thin film described above.

In the method for manufacturing a silicon-containing thin film according to an exemplary embodiment, a thin film is manufactured using a composition for depositing a silicon-containing thin film including the alkoxyaminosilylamine compound which is thermally stable and highly volatile as a precursor, whereby a silicon-containing thin film having excellent characteristics may be manufactured.

The method for manufacturing a silicon-containing thin film according to an exemplary embodiment may be any method allowed within a range which may be recognized by a person skilled in the art, and preferably, may be performed by atomic layer deposition (ALD), chemical vapor deposition (CVD), metalorganic chemical vapor deposition (MOCVD), low pressure chemical vapor deposition (LPCVD), plasma-enhanced chemical vapor deposition (PECVD), or plasma-enhanced atomic layer deposition (PEALD), and plasma-enhanced chemical vapor deposition (PECVD) or plasma-enhanced atomic layer deposition (PEALD) is preferred in terms of easier thin film deposition and excellent properties of a manufactured thin film.

The method for manufacturing a silicon-containing thin film according to a specific example may include, specifically, a) heating a temperature of a substrate mounted in a chamber to 30 to 400° C. and maintaining the temperature; b) bringing the substrate into contact with the composition for depositing a silicon-containing thin film according to an exemplary embodiment to adsorb the composition onto the substrate; and c) injecting a reaction gas to deposit a silicon-containing thin film on the substrate.

Preferably, when depositing the silicon-containing thin film according to a specific example of the present disclosure by plasma-enhanced atomic layer deposition (PEALD) or plasma-enhanced chemical vapor deposition (PECVD), a step of generating plasma may be further included after step a). In addition, in step b), the composition for depositing a silicon-containing thin film according to an exemplary embodiment may be injected with a transport gas.

In the method for manufacturing a silicon-containing thin film according to an exemplary embodiment, deposition conditions may be adjusted depending on the structure or thermal properties of the thin film to be desired, and as the deposition conditions according to a specific example, an input flow rate of the composition for depositing a silicon-containing thin film containing the alkoxyaminosilylamine compound, input flow rates of reaction gas and carrier gas, pressure, RF power, a substrate temperature and the like may be exemplified, and as a non-limited example of the deposition condition, the conditions may be adjusted in the following ranges, but are not limited thereto: an input flow rate of the composition for depositing a silicon-containing thin film of 10 to 1000 cc/min, a flow rate of the carrier gas of 10 to 1000 cc/min, a flow rate of the reaction gas of 1 to 1000 cc/min, a pressure of 0.5 to 10 torr, an RF power of 200 to 1000 W, and a substrate temperature of 30 to 400° C., preferably 100 to 350° C.

The silicon-containing thin film according to an exemplary embodiment may be any film which may be manufactured within a range which may be recognized by a person skilled in the art, and specifically, may be a silicon oxide film (SiO₂), a silicon oxycarbide film (SiOC), a silicon nitride film (SiN), a silicon oxynitride film (SiON), a silicon carbonitride film (SiCN), or a silicon carbide film (SiC), and the like, and various high-quality thin films including silicon within a range which may be recognized by a person skilled in the art may be manufactured.

The reaction gas used in the method for manufacturing a silicon-containing thin film according to an exemplary embodiment may be any gas which is commonly used with a silicon precursor considering the a material of the silicon-containing thin film to be manufactured, and as a specific example, may be any one or two or more selected from oxygen (O2), ozone (O₃), distilled water (H₂O), hydrogen peroxide (H₂O₂), nitrogen monoxide (NO), nitrous oxide (N₂O), nitrogen dioxide (NO₂), ammonia (NH₃), nitrogen (N₂), hydrazine (N₂H₄), amine, diamine, carbon monoxide (CO), carbon dioxide (CO₂), C1 to C12 saturated or unsaturated hydrocarbon, hydrogen, argon, and helium, and the transport gas may be one or two or more selected from argon, helium, and nitrogen, but the present disclosure is not limited thereto.

The substrate used in the method for manufacturing a silicone-containing thin film according to a specific example may be a substrate including one or more semiconductor materials of Si, Ge, SiGe, GaP, GaAs, SiC, SiGeC, InAs, and InP; a silicon on insulator (SOI) substrate; a quartz substrate; a glass substrate for display; a flexible plastic substrate such as polyimide, polyethylene terephthalate (PET), polyethylene naphthalate (PEN), polymethyl methacrylate (PMMA), polycarbonate (PC), polyethersulfone (PES), and polyester; and the like, but is not limited thereto.

In addition, in addition to formation of the silicon-containing thin film directly on the substrate, a plurality of conductive layers, dielectric layers, insulating layers, or the like may be formed between the substrate and the silicon-containing thin film.

Hereinafter, the examples of the present disclosure will be described in detail. However, they are provided so that the present disclosure may be easily carried out by those skilled in the art, the present disclosure may be implemented in various forms, and the idea of the present disclosure is not necessarily limited to the examples.

Hereinafter, the structure of the alkoxyaminosilylamine compound according to an exemplary embodiment of the present disclosure was analyzed by ¹H NMR, ¹³C NMR, and ²⁹Si-NMR spectra.

In addition, the thermal stability, volatility, and decomposition temperature of the obtained alkoxyaminosilylamine compound were measured by thermogravimetric analysis (TGA) and differential scanning calorimeter (DSC).

### [Example 1] Synthesis of Bis[Dimethylmethoxysilyl](Dimethylsilyl)Amine

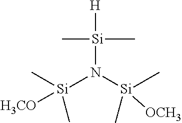

206 g (2.39 mol) of hexane (C6H₁₄) and 71.3 g (0.37 mol) of bis(methoxydimethylsilyl)amine ([(CH₃)₂(OCH₃)Si]₂NH) were added to a flame dried 2 L flask under an anhydrous and inert atmosphere, n-butyllithium (2.68 M, 137.8 ml) was slowly added thereto while maintaining the internal temperature at −20° C., the reaction solution was slowly brought to normal temperature, and stirring was performed at normal temperature for 4 hours. 95.3 g (1.11 mol) of hexane (C₆H₁₄) and 34.9 g (0.37 mol) of chlorodimethylsilane ((CH₃)₂ClSiH) were added to a flame dried 2 L flask under an anhydrous and inert atmosphere, 73.5 g (0.37 mol) of a produced bis(methoxydimethylsilyl)amine lithium salt ([(CH₃)₂(OCH₃)Si]₂NLi) was slowly added while maintaining the temperature at −20° C., the reaction solution was slowly brought to normal temperature, and stirring was performed at normal temperature for 4 hours. After the reaction was completed, the reaction mixture was filtered to remove a lithium chloride salt (LiCl), the solvent was removed from the obtained filtrate under reduced pressure, and distillation under reduced pressure was performed to obtain 53.7 g (0.21 mol) of the title compound, bis[methoxydimethylsilyl](dimethylsilyl)amine. (yield: 57.9%).

¹H-NMR (C₆D₆): δ 4.76(m, 1H (SiH(CH₃)₂), δ 3.25(s, 6H (CH₃)₂(OCH₃)Si, δ 0.35(d, 6H (SiH(CH₃)₂), δ 0.25(s, 12H [(CH₃)₂(OCH₃)Si]₂N)

²⁹Si-NMR (C₆D₆) δ-13.71 (SiH(CH₃)₂) δ 1.34 ([(CH₃)₂(OCH₃)Si]₂N)

### [Example 2] Synthesis of Bis[Dimethylmethoxysilyl](Methylsilyl)Amine

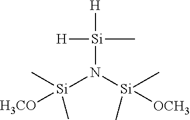

379.3 g (4.40 mol) of hexane (C₆H₁₄) and 170.3 g (0.88 mol) of bis(methoxydimethylsilyl)amine ([(CH₃)₂(OCH₃)Si]₂NH) were added to a flame dried 2 L flask under an anhydrous and inert atmosphere, n-butyllithium (2.60 M, 339.5 ml) was slowly added thereto while maintaining the internal temperature at −20° C., and stirring was performed at normal temperature for 4 hours to prepare 175.5 g (0.88 mol) of a bis(methoxydimethylsilyl)amine lithium salt ([(CH₃)₂(OCH₃)Si]₂NLi).

227.6 g (2.64 mol) of hexane (C₆H₁₄) and 101.3 g (0.88 mol) of dichloromethylsilane ((CH₃)Cl₂SiH) were added to a flame dried 3 L flask under an anhydrous and inert atmosphere, 175.5 g (0.88 mol) of a produced bis(methoxydimethylsilyl)amine lithium salt ([(CH₃)₂(OCH₃)Si]₂NLi) was slowly added while maintaining the temperature at −20° C., the reaction solution was slowly brought to normal temperature, and stirring was performed at normal temperature for 4 hours. After the reaction was completed, the reaction mixture was filtered to remove a lithium chloride salt (LiCl), the solvent was removed from the obtained filtrate under reduced pressure, and distillation under reduced pressure was performed to obtain 213.0 g (0.78 mol) of bis(methoxydimethylsilyl](chloromethylsilyl)amine ([(CH₃)₂(OCH₃)Si]₂N—SiHCl(CH₃)). (yield: 88.6%).

225.9 g (3.13 mol) of tetrahydrofuran (C₄H₈O) and 213.0 g (0.78 mol) of bis(methoxydimethylsilyl](chloromethylsilyl)amine ([(CH₃)₂(OCH₃)Si]₂N—SiHCl(CH₃)) were added to a flame dried 1 L flask under an anhydrous and inert atmosphere, 6.23 g (0.78 mol) of lithium hydride (LiH) was slowly added at normal temperature, the reaction solution was slowly brought to normal temperature, and stirring was performed at normal temperature for 18 hours. After the reaction was completed, the reaction mixture was filtered to remove a lithium chloride salt (LiCl), the solvent was removed from the obtained filtrate under reduced pressure, and distillation under reduced pressure was performed to obtain 93.0 g (0.39 mol) of the title compound, bis[methoxydimethylsilyl](methylsilyl)amine ([(CH₃)₂(OCH₃)Si]₂N—SiH₂ (CH₃)). (yield: 50.0%).

¹H-NMR (C₆D₆): δ 4.68(m, 2H (SiH₂(CH₃)), δ 3.28(s, 6H (CH₃)₂(OCH₃)Si, δ 0.29(t, 3H (SiH₂ (CH₃)), δ 0.24(s, 12H [(CH₃)₂(OCH₃)Si]₂N)

²⁹Si-NMR (C₆D₆): δ-33.0 (SiH₂(CH₃)) δ 0.98 ([(CH₃)₂(OCH₃)Si]₂N)

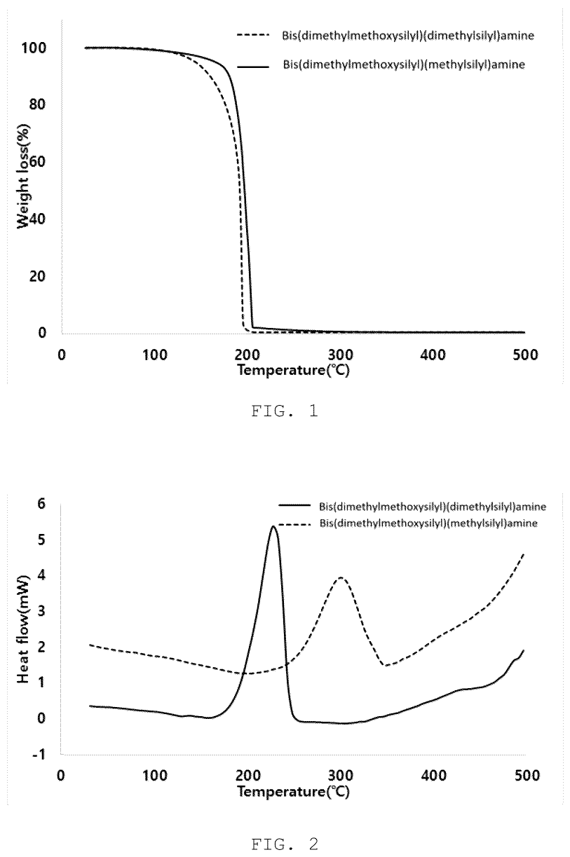

From FIGS. 1 and 2, the high volatility, stability, and thermal decomposition properties of the alkoxyaminosilylamine compound precursors prepared by the above method were able to be confirmed.

The present disclosure has been described in detail in specific parts, and it is obvious that such specific technique is only a preferred embodiment to a person skilled in the art, without limiting the scope of the present disclosure. Thus, the substantial scope of the present disclosure will be defined by the appended claims and their equivalents.

1. An alkoxyaminosilylamine compound represented by the following Chemical Formula 1: 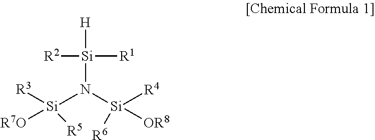
wherein R¹ to R⁴ are independently of one another hydrogen, C1-C10 alkyl, C2-C10 alkenyl, or halogen; and
wherein R⁵ to R⁸ are independently of one another C1-C10 alkyl.

2. The alkoxyaminosilylamine compound of claim 1,
wherein R¹ to R⁴ are independently of one another hydrogen, C1-C5 alkyl, C2-C5 alkenyl, or halogen; and
wherein R⁵ to R⁸ are independently of one another C1-C5 alkyl.

3. The alkoxyaminosilylamine compound of claim 1,
wherein R¹ to R⁴ are independently of one another hydrogen or C1-C5 alkyl; and
wherein R⁵ to R⁸ are independently of one another C1-C5 alkyl.

4. The alkoxyaminosilylamine compound of claim 1, wherein the alkoxyaminosilylamine compound is selected from the following compounds:

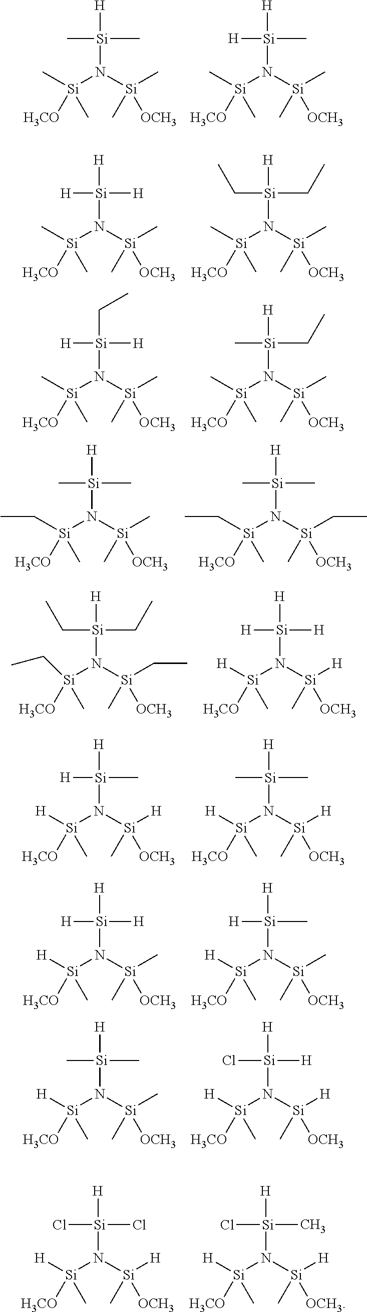

5. A method for preparing an alkoxyaminosilylamine compound, the method comprising: reacting a compound of the following Chemical Formula 3 and a compound of the following Chemical Formula 4 in the presence of C1-C5 alkyllithium to prepare an alkoxyaminosilylamine compound of the following Chemical Formula 1: 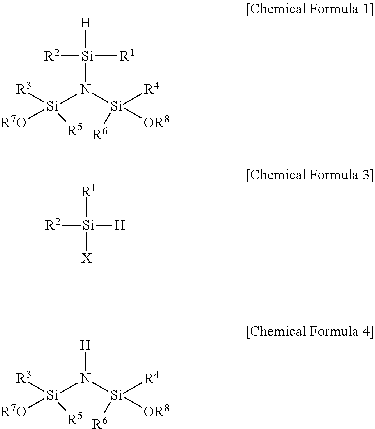
wherein R¹ to R⁴ are independently of one another hydrogen, C1-C10 alkyl, C2-C10 alkenyl, or halogen;
wherein R⁵ to R⁸ are independently of one another C1-C10 alkyl; and
wherein X is a halogen.

6. A method for preparing an alkoxyaminosilylamine compound, the method comprising: reacting a compound of the following Chemical Formula 4 and a compound of the following Chemical Formula 5 in the presence of C1-C5 alkyllithium to prepare a compound of the following Chemical Formula 6; and adding a reducing agent to the compound of Chemical Formula 6 to prepare an alkoxyaminosilylamine compound of the following Chemical Formula 1-1: 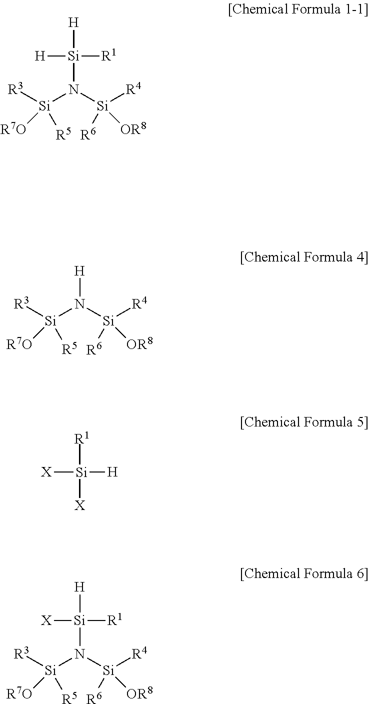
wherein R¹, R³, and R⁴ are independently of one another hydrogen, C1-C10 alkyl, C2-C10 alkenyl, or halogen;
wherein R⁵ to R⁸ are independently of one another C1-C10 alkyl; and
wherein X is a halogen.

7. A composition for depositing a silicon-containing thin film comprising an alkoxyaminosilylamine compound represented by the following Chemical Formula 2: 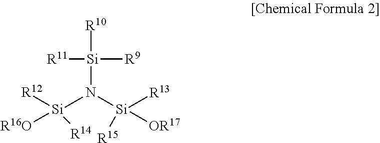
wherein R⁹ to R¹³ are independently of one another hydrogen, C1-C10 alkyl, C2-C10 alkenyl, or halogen; and
wherein R¹⁴ to R¹⁷ are independently of one another C1-C10 alkyl.

8. The composition for depositing a silicon-containing thin film of claim 7,
wherein R⁹ to R¹³ are independently of one another hydrogen, C1-C5 alkyl, C2-C5 alkenyl, or halogen; and
wherein R¹⁴ to R¹⁷ are independently of one another C1-C5 alkyl.

9. The composition for depositing a silicon-containing thin film of claim 7, wherein Chemical Formula 2 is selected from the following compounds:

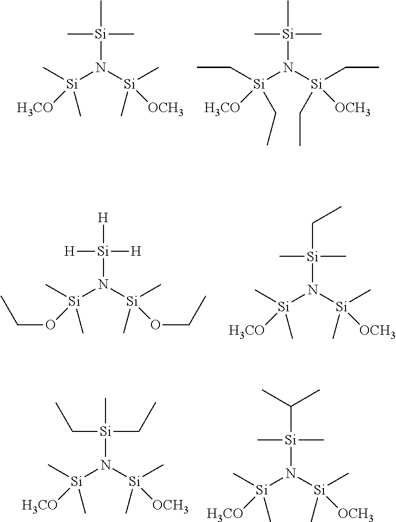

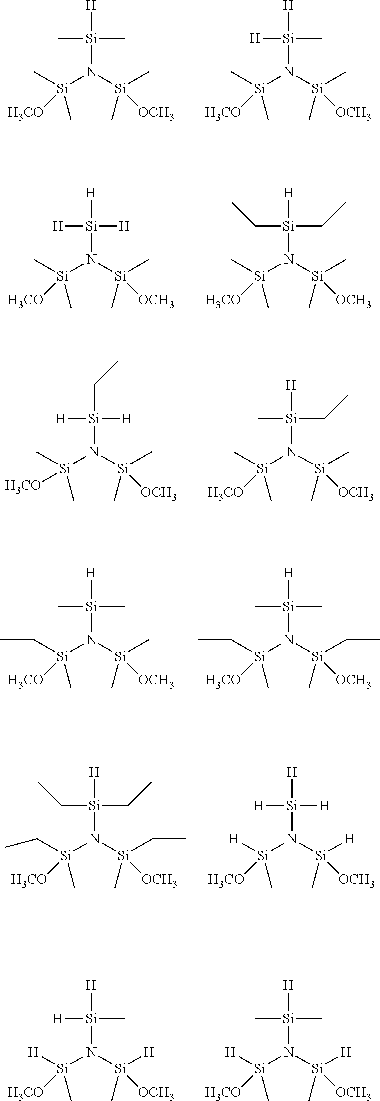

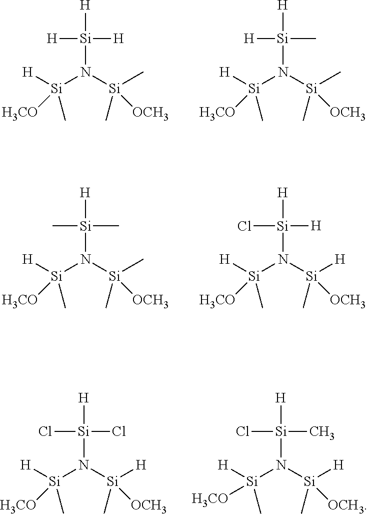

10. A method for manufacturing a silicon-containing thin film, the method comprising manufacturing a thin film using the alkoxyaminosilylamine compound of claim 1.

11. A method for manufacturing a silicon-containing thin film, the method comprising manufacturing a thin film using the composition for depositing a silicon-containing thin film of claim 7.
